(19) United States
(12) Patent Application Publication
(10) Pub. No.: US 2006/0023437 A1
(43) Pub. Date: Feb. 2, 2006

(54) Electronic device with display tube

(75) Inventor: Kazufumi Nishida, Takefu-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD., Takefu-city (JP)

(21) Appl. No.: 11/189,915

(22) Filed: Jul. 27, 2005

(30) Foreign Application Priority Data
Jul. 30, 2004 (JP) 2004-224119

(51) Int. Cl. H05K 7/06

(52) U.S. Cl. 361/760; 361/781

(57) ABSTRACT

The invention provides an electronic device with a display tube having excellent impact-resistant property, capable of preventing a display tube mounted on a circuit board from tilting toward or falling on the circuit board upon receiving impact when the device is dropped or during mounting operations. A fluorescent display tube 10 is mounted on a circuit board 3 on which various electronic components 4 are mounted, and a switch 20 that does not constitute a circuit with a circuit pattern 6 on the circuit board 3 is soldered and fixed between the fluorescent display tube 10 and the circuit board 3. When impact is applied to the fluorescent display tube 10 by erroneously dropping the device or the like, or when external force is applied to the fluorescent display tube 10 when mounting the same to the circuit board 3, the switch 20 supporting the fluorescent display tube 10 supports the tube 10 so as not to tilt or fall from the predetermined mounting position and relieves impact, thereby providing impact-resistant property to the electronic device.

The present application is based on and claims priority of Japanese patent application No. 2004-224119 filed on Jul. 30, 2004, the entire contents of which are hereby incorporated by reference.

### BACKGROUND OF THE INVENTION

1. Field of the Invention

The present invention relates to an electronic device with a display tube, and especially to an electronic device with a display tube having an electronic component for supporting the display tube provided between the circuit board of the electronic device and the display tube, thereby preventing the tube from tilting toward the circuit board when the device receives impact from the exterior by being dropped or during assembly of the device.

2. Description of the Related Art

Various electronic devices such as audio devices, office machines, communication equipments, television receivers and DVD players are equipped with display tubes so-called vacuum fluorescent displays (VFD) for indicating the control status or operation status of the device. Further, the electronic devices have in the casing thereof a flat plate-shaped circuit board mounting various electronic components, wherein the display tube is mounted on the circuit board by soldering connecting terminals protruded from the display tube body onto the circuit board. Examples of such prior art are disclosed in Japanese Utility Model Publication No. 3072266 (patent document 1) and Japanese Utility Model Publication No. 3086332 (patent document 2). For example, patent document 1 discloses a mounting structure of a display tube in which a display tube soldered via connecting terminals onto the wiring board is supported by being sandwiched between supporting bodies that prevent the tube from tilting. Further, patent document 2 discloses a mounting structure for mounting on a board a fluorescent display tube that is mounted aslant on the board. According to patent document 2, since the fluorescent display tube is mounted aslant on the board, the display tube is fixed by a support member provided on the board and a parallel support portion projected from a front cabinet so as to ensure the mounting strength thereof.

Further, Japanese Patent Application Laid-Open Publication No. 2003-318505 (patent document 3) discloses mounting plural electronic components on a printed board, wherein electronic components with a height higher than the electronic component such as a memory that is fragile to impact from the exterior and must be protected from impact is mounted on the printed board, wherein the high electronic components are provided as dummy components which are not electrically connected to the circuit of the printed board, by which the fragile electronic component such as the memory is protected from impact from the exterior. Japanese Patent Application Laid-Open Publication No. 2001-34191 (patent document 4) discloses providing tongue-shaped pieces on the loading surface of a holder for placing a fluorescent display tube, wherein the front ends thereof are provided with pressing projections projecting from the loading surface. The fluorescent display tube is mounted on the loading surface of the holder, and a cover pressing the fluorescent display tube is fixed to the substrate, so that the fluorescent display tube is elastically held between the pressing projection and the cover.

According to patent documents 1 and 2 mentioned above, a dedicated mounting structure or mounting member is provided to support the display tube via projected connecting terminals provided on the display tube soldered on the circuit board, and thus the display tube is supported in a stable manner, but various mounting members must be prepared in advance to mount the display tube stably. Thus, the number of components that must be mounted on the board and the mounting area are increased, which requires much mounting operation time and increases related costs.

Further, patent document 3 discloses an art of arranging dummy chip components that are not electrically connected to the circuit around the memory to be protected in order to protect electronic components mounted on the printed circuit board from impact caused by dropping or the like. However, if impact is caused by dropping or the like, by simply surrounding the memory to be protected with dummy chip components having a height higher than the memory, the direct contact of the memory with the floor can be prevented when dropped, but the dummy chip components mounted on the printed board inside the device may cause short circuit. On the other hand, if the dummy chips mounted on the printed board are to be removed from the board, the removing of the chips takes up much time, and as a result, such troublesome work increases costs and deteriorates productivity.

Patent document 4 discloses a display device capable of preventing generation of rattle noise caused by collision of the fluorescent display tube against surrounding members, by mounting the fluorescent display tube on a holder on a board and providing an elastic projection between the holder and the fluorescent display tube to relieve the shock of impact when the fluorescent display tube collides against surrounding members. It may be possible to prevent the generation of rattle noise by providing an elastic projection between the board and the holder, but since the projection is only very slightly projected from the loading surface of the holder, the elastic projection is not sufficient to relieve the impact applied to the display device from the exterior.

### SUMMARY OF THE INVENTION

The present invention aims at solving the problems of the prior art, by providing an electronic device having a display tube with superior impact-resistant property, capable of preventing the display tube mounted on the circuit board of the electronic device from tilting toward or falling on the circuit board when impact is received by dropping the device or when mounting the display tube on the electronic device.

A first aspect of the present invention relates to an electronic device with a display tube having at least the display tube mounted on a circuit board, wherein the display tube has a terminal bent into an L-shape, the terminal being connected to the circuit board so that the display tube is arranged substantially in parallel with the circuit board with a space therebetween, further comprising an electronic component connected to the circuit board and in contact with a rear surface of the display tube so as to support the display tube, the electronic component being soldered so as not to constitute a circuit with a circuit pattern formed to the circuit board.

According to the first aspect of the present invention, the electronic component supporting the display tube is a general-purpose, mass-produced inexpensive electronic component which can be easily soldered onto the circuit board, so the present electronic device has superior versatility and is cost-effective. Further, since the display tube is supported by the electronic component that does not constitute a circuit with the circuit pattern, the display tube will not tilt or fall from the determined mounting position even when the display tube receives impact by being dropped or when external force is applied to the display tube when being mounted on the circuit board.

A second aspect of the present invention relates to the electronic device with a display tube according to the first aspect, wherein the electronic component is a switch having a control key that snaps back to its original form, the control key being in contact with the rear surface of the display tube.

According to the second aspect of the invention, a control key provided on a switch that retreats when pressed and snaps back to its original form when released is in contact with the display tube mounted on the circuit board, so that when the display tube receives impact due to fall or when relatively large force from the exterior is applied to the display tube when being mounted on the circuit board, the impact or external force applied to the display tube is absorbed and relieved by the control key provided on the switch in contact with the display tube by being pressed by the display tube and retreating. Thereby, the present electronic device has impact-resistance.

A third aspect of the present invention relates to the electronic device with a display tube according to the first aspect, wherein the electronic component is an automatically mountable component that can be mounted automatically and mechanically to the circuit board.

According to the third aspect of the invention, the electronic component is an automatically mountable component that can be mounted automatically to the circuit board, so the electronic component does not have to be mounted manually but can be mounted automatically using an automated production means such as a robot, and manual mounting work can be cut down.

### BRIEF DESCRIPTION OF THE DRAWINGS

FIG. 1 is a front view showing the arrangement of an electronic device with a display tube according to the present invention;

FIG. 2 is a cross-sectional view showing the main portion of the electronic device with a display tube according to the present invention;

FIG. 3 is a perspective view showing the switch fixed to the circuit board inside the electronic device according to the present invention;

FIG. 4 is a plan view showing the connection of the circuit pattern and the switch, wherein FIG. 4(a) is a plan view in which the switch is connected to a dummy pattern, FIG. 4(b) is a plan view in which the switch is connected to one of the electrode lines, and FIG. 4(c) is a plan view in which the switch is connected to a circuit pattern and a dummy pattern; and

FIG. 5 is a perspective view showing an electrolytic capacitor fixed to a circuit board inside the electrode device according to a modified example of the present embodiment.

### DETAILED DESCRIPTION OF THE PREFERRED EMBODIMENTS

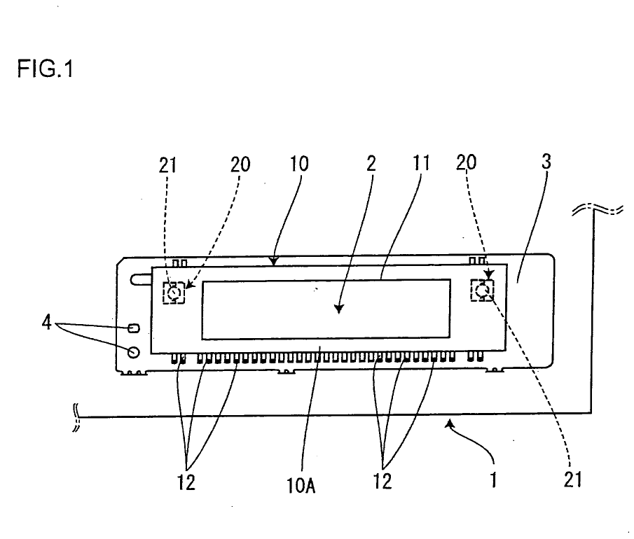

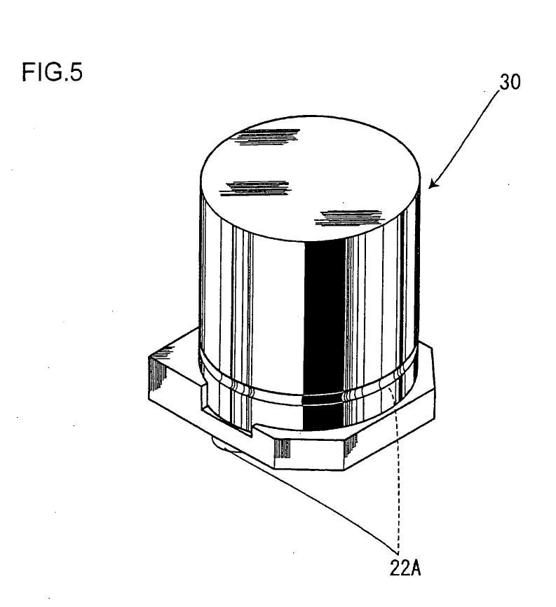

Now, the preferred embodiments for carrying out the present invention will be described with reference to FIGS. 1 through 5. The technical scope of the present invention is not restricted to the language used in the embodiments, but is extended to the range in which a person skilled in the art could easily substitute based on the present disclosure.

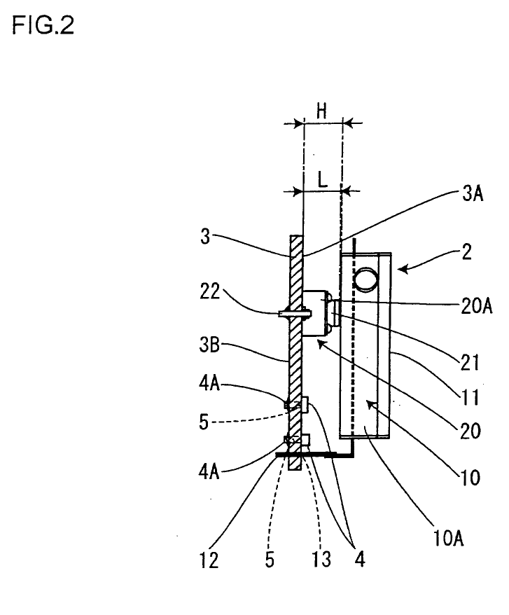

FIG. 1 is a front view showing a display device provided in an electronic device according to one example of the present invention, and FIG. 2 is a cross-sectional view thereof.

As shown in FIGS. 1 and 2, a display device 2 mounted on an electronic device 1 is fixed to a circuit board 3 that is screw-engaged inside the electronic device 1. On a mounting surface 3A of the plate-like circuit board 3 are mounted various electronic components 4 such as a resistor and a condenser, and the various electronic components 4 are each provided with integral connecting terminals 4A. A circuit pattern 6 is formed on a rear surface 3B opposite from the mounting surface 3A of the circuit board 3, and the connecting terminals 4A are inserted to through holes 5 provided on the circuit pattern 6, by which the various electronic components 4 are electrically connected and fixed to the circuit pattern 6 via soldering. For example, the circuit pattern 6 includes an anode line 6A and a cathode line 6B, and the circuit pattern 6 can be electronically connected with the electronic components 4 by soldering the terminals 4A of the electronic components 4 to the anode line 6A and cathode line 6B.

Reference number 10 denotes a fluorescent display tube for indicating the control status or the operation status of the electronic device. The fluorescent display tube 10 is a display device so-called a vacuum fluorescent display (VFD), which is a flat-shaped tube shaped differently from a vacuum tube. The fluorescent display tube 10 has a display unit 11 on which the control status or the like is indicated, and the display unit 11 is self-luminous.

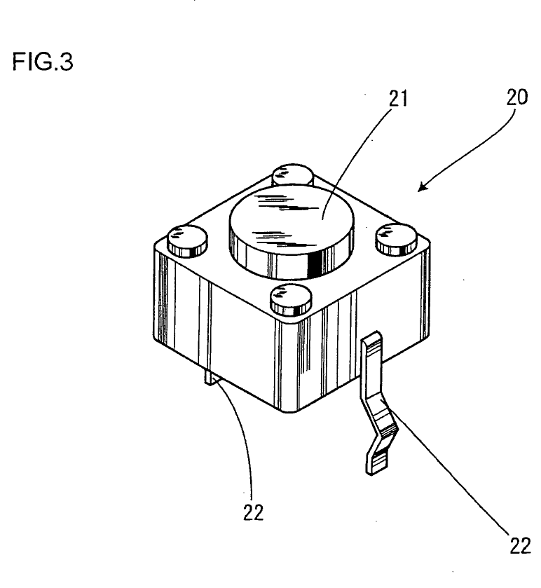

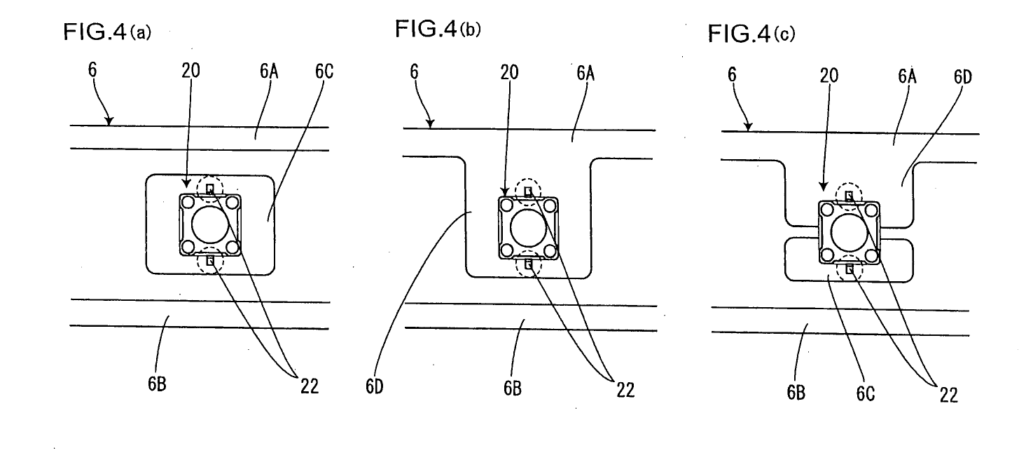

Furthermore, as shown in FIG. 1, the fluorescent display tube 10 has multiple L-shaped terminals 12 projecting from the side opposite from where the display unit 11 is provided on the display tube 10, and these terminals 12 are soldered and fixed to the circuit pattern 6 attached to the rear surface 3B of the circuit board 3 via holes 13 provided on the circuit board 3, as shown in FIG. 2. That is, as shown in FIG. 2, the rectangular body 10A of the fluorescent display tube 10 is supported open-sidedly by L-shaped terminals 12 and disposed in parallel with the circuit board 3 with a space therebetween, the length L between the rectangular body 10A of the fluorescent display tube 10 and the circuit board 3 being approximately 5.2 mm, and a switch 20 is provided between the circuit board 3 and the body 10A of the fluorescent display tube 10 as a dummy electronic component that does not constitute a circuit with the circuit pattern 6. The height H of a switch body 20A omitting terminals 22 from the switch 20 is 5.0 mm, and the upper and lower portions of the switch body 20A are respectively in contact with the body 10A of the fluorescent display tube 10 and the circuit board 3, supporting the fluorescent display tube 10 from its rear side. In order to prevent electronic trouble from occurring between the fluorescent display tube 10 and the switch 20, the terminals 22 of the switch 20 are soldered onto a dummy pattern 6C formed independently from the circuit pattern 6, as illustrated in FIG. 4(a), so that the switch 20 and the fluorescent display tube 10 do not constitute a circuit with the circuit pattern 6. Other arrangements in which the switch 20 and the fluorescent display tube 10 do not constitute the circuit include, for example, the arrangement shown in FIG. 4(b) in which all the terminals 22 of the switch 20 are soldered onto an additional pattern 6D extended integrally from the anode line 6A of the circuit pattern 6, or the arrangement shown in FIG. 4(c) in which a part of the terminals 22 of the switch 20 are soldered onto the anode line 6A of the circuit pattern 6 while the remaining terminals are soldered onto a dummy pattern 6C formed integrally to the circuit pattern 6, but in any case, the switch 20 mounted as a dummy electronic component should simply not constitute a circuit with the circuit pattern 6. Thus, the switch 20 that does not constitute a circuit with the circuit pattern 6 supports the fluorescent display tube 10. Further, as shown in FIGS. 2 and 3, a control key 21 is integrally formed to the upper side (right side in FIG. 2) of the switch 20, which is retreated when pressed from above and restored to its original shape when released, that is, the control key has elasticity and can snap back to its original state, so that when the fluorescent display tube 10 inside the electronic device 1 receives impact when the device is erroneously dropped on the floor or the like, or when a relatively strong force is applied to the fluorescent display tube from the exterior when mounting the display tube on the circuit board 3 screw-engaged to the electronic device 1, the control key 21 having elasticity absorbs and relieves the impact. Costs can be cut down by selecting and using an inexpensive mass-produced component as the switch 20.

As a modified example, an electrolytic capacitor 30 shown in FIG. 4 or a connector not shown can be used instead of the switch 20. In such cases, though the component may not have elasticity like the switch 20, an inexpensive mass-produced general-purpose electronic component can be simply soldered to the circuit board 3 to be utilized for supporting the fluorescent display tube 1. As explained, by utilizing a component that does not constitute a circuit with the circuit pattern 6, such as an electrolytic capacitor 30 or a connector used as a dummy component, to support the fluorescent display tube 10, the electronic device 1 can be provided at lower cost compared to the case in which an expensive dedicated component is used to support the fluorescent display tube 10.

Further, the electronic component such as the switch 20, the electrolytic capacitor 30 or the connector that does not constitute a circuit with the circuit pattern has terminals 22 or 22A formed integrally thereto, and the terminals can be soldered onto the circuit board 3, so the component is generally an automatically mountable component that can be mounted automatically on the circuit board of the electronic device. Therefore, the component that does not constitute a circuit with the circuit pattern can be mounted on the circuit board 3 not manually but automatically, so by utilizing an automated production means, manual mounting work can be minimized.

As described, according to the electronic device 1, the electronic device 1 with a fluorescent display tube 10 has the fluorescent display tube 10 mounted to a circuit board 3 having mounted thereto various electronic components 4, and a dummy electronic component such as a switch 20, an electrolytic capacitor 30 or a connector that is in contact with the rear surface of the fluorescent display tube 10 to support the tube 10 is soldered onto the circuit board 3 so as not to constitute a circuit with the circuit pattern 6. According to this arrangement, the electronic component such as the switch 20 is an inexpensive, general-purpose and mass-produced electronic component, which can be easily soldered onto the circuit board 3, and so the cost of the electronic device can be cut down. Further, by having a dummy electronic component mounted on the circuit board 3 that does not constitute a circuit with the circuit pattern 6 contact the fluorescent display tube 10 mounted on the circuit board 3, when the fluorescent display tube 10 receives impact by being dropped or the like, or when force is applied from the exterior when mounting the fluorescent display tube 10 to the circuit board 3, the electronic component such as the switch 20, the electrolytic capacitor 30 or the connector that does not constitute a circuit with the circuit pattern 6 on the circuit board 3 supports the fluorescent display tube 10 so that it will not tilt or fall from the determined mounting position. Therefore, the electronic device 1 being provided has improved reliability and has superior impact-resistance that can support the fluorescent display tube 10 without fail. Further, the electronic component such as the switch 20 is a component that can be mounted automatically using a machine to the circuit board 3, so that an automated production means such as a robot can be used to mount the electronic component such as the switch 20 and manual mounting operations can be cut down. Therefore, the electronic device 1 can be manufactured at low cost and has improved productivity with reduced mounting work time. Furthermore, the switch 20 used as a dummy electronic component includes a control key having elasticity which retreats when pressed and returns to its original form when released, so that when the control key 21 that retreats when the switch 20 is pressed and returns to its original form when released is mounted on the circuit board 3 in contact with the fluorescent display tube 10 mounted on the circuit board 3, the control key 20A of the witch 20 in contact with the fluorescent display tube 10 mounted on the circuit board 3 enables to absorb and relieve the impact applied to the fluorescent display tube 10 when the device is dropped or the like or when relatively large external force is applied to the fluorescent display tube 10 upon mounting the same to the circuit board 3, by retreating when pressed by the display tube. Thus, an electronic device 1 capable of preventing damage from being caused thereto is provided. Furthermore, since the electrolytic capacitor 30, the switch 20 or the connector can be automatically mounted on the electronic device 1, cost of the device can be cut down by using relatively inexpensive general-purpose, inexpensive electronic components such as the electrolytic capacitor 30, the switch 20 or the connector as mounting components. Moreover, since the dummy switch 20, the electrolytic capacitor 30 or the connector supporting the fluorescent display tube 10 is soldered onto the circuit board 3 without constituting a circuit with the circuit pattern 6 formed to the circuit board 3, electric trouble caused by short-circuiting of the fluorescent display tube 20 with the dummy switch 20, the electrolytic capacitor 30 or the connector supporting the display tube can be prevented without fail.

The effects of the invention are as follows.

The first aspect of the present invention relates to an electronic device with a display tube having at least the display tube mounted on a circuit board, wherein the display tube has a terminal bent into an L-shape, the terminal being connected to the circuit board so that the display tube is arranged substantially in parallel with the circuit board with a space therebetween, further comprising an electronic component connected to the circuit board and in contact with a rear surface of the display tube so as to support the display tube, the electronic component being soldered so as not to constitute a circuit with a circuit pattern formed to the circuit board. Thus, the present invention utilizes a general-purpose mass-produced inexpensive electronic component to support the display tube, so the present electronic device has superior versatility and is cost effective. Even further, the display tube is supported by an electronic component that does not constitute a circuit with the circuit pattern so as not to tilt or fall from its determined mounting position when it receives impact by being dropped or when external force is applied to the display tube from the exterior during mounting of the tube to the circuit board, so the present electronic device has superior impact-resistance and improved reliability with less malfunction.

The second aspect of the present invention relates to the electronic device with a display tube according to the first aspect, wherein the electronic component is a switch having a control key that snaps back to its original position, the control key being in contact with the rear surface of the display tube. When the display tube receives impact by being dropped or when relatively large external force is applied to the display device when mounting the same to the circuit board, the impact received by the display tube can be absorbed and relieved by the control key of the switch being retreated, by which the device is provided with impact resistance. Thus, the present invention provides a damage-proof electronic device.

The third aspect of the present invention relates to the electronic device with a display tube according to the first aspect, wherein the electronic component is an automatically mountable component that can be mounted automatically and mechanically to the circuit board. Since the electronic component is an automatically mountable component that can be mounted automatically to the circuit board, the electronic component does not have to be mounted manually but can be mounted automatically using an automated production means such as a robot. Thus, the present invention can provide an electronic device having reduced mounting work time and improved productivity.

What is claimed is:

1. An electronic device with a display tube having at least the display tube mounted on a circuit board, wherein the display tube has a terminal bent into an L-shape, the terminal being connected to the circuit board so that the display tube is arranged substantially in parallel with the circuit board with a space therebetween, further comprising an electronic component connected to the circuit board and in contact with a rear surface of the display tube so as to support the display tube, the electronic component being soldered so as not to constitute a circuit with a circuit pattern formed to the circuit board.

2. The electronic device with a display tube according to claim 1, wherein the electronic component is a switch having a control key that snaps back to its original form, the control key being in contact with the rear surface of the display tube.

3. The electronic device with a display tube according to claim 1, wherein the electronic component is an automatically mountable component that can be mounted automatically and mechanically to the circuit board.
